(19) United States
(12) Patent Application Publication
(10) Pub. No.: US 2025/0376053 A1
(43) Pub. Date: Dec. 11, 2025

(54) APPARATUS AND METHOD OF DETECTING DETERIORATION OF CHARGING TERMINAL

(71) Applicants: HYUNDAI MOTOR COMPANY, SEOUL (KR); KIA CORPORATION, SEOUL (KR)

(72) Inventor: Tae Hwan KANG, Hwaseong-si (KR)

(21) Appl. No.: 18/947,564

(22) Filed: Nov. 14, 2024

(30) Foreign Application Priority Data
Jun. 10, 2024 (KR) 10-2024-0074928

(51) Int. Cl. B60L 53/16; B60L 53/10; G01R 31/58

(52) U.S. Cl. CPC B60L 53/16; B60L 53/11; G01R 31/58

(57) ABSTRACT

An apparatus for detecting a deterioration of a rapid charging terminal includes one or more processors and a storage medium storing a computer-readable instruction, wherein, when the computer-readable instruction is executed by the one or more processors, the one or more processors are configured to measure an inter-terminal voltage due to a contact resistance between rapid charging terminals respectively provided in an inlet and an outlet, while rapid charging is performed, and determine whether the rapid charging terminal is deteriorated based on the measured inter-terminal voltage, and wherein the voltage is measured using a terminal not used for rapid charging among the terminals provided in the inlet and the outlet.

### CROSS-REFERENCE TO RELATED APPLICATION(S)

This application claims benefit of priority to Korean Patent Application No. 10-2024-0074928 filed on Jun. 10, 2024 in the Korean Intellectual Property Office, the disclosure of which is incorporated herein by reference in its entirety.

### BACKGROUND

### 1. Field

The present disclosure relates to an apparatus and method of detecting deterioration of a rapid charging terminal.

### 2. Description of Related Art

When an electric vehicle is rapidly charged, a large current (e.g., up to 500 A) flows, so it is necessary to minimize contact resistance between a rapid charging terminal of an outlet connected to a charging facility and a rapid charging terminal of an inlet connected to a vehicle.

However, if rapid charging is repeated, the rapid charging terminal may deteriorate (i.e., the state thereof may deteriorate) and the contact resistance may increase.

The increase in contact resistance may generate an arc and heat in a contact portion between the rapid charging terminals, which may cause fusion in which the rapid charging terminals momentarily stick together.

### SUMMARY

An aspect of the present disclosure is to provide an apparatus and method of detecting deterioration of a rapid charging terminal, capable of detecting whether a rapid charging terminal is deteriorated during rapid charging. One advantage of the present disclosure is the ability to detect deterioration in advance, before fusion occurs.

According to an aspect of the present disclosure, an apparatus of detecting a deterioration of a rapid charging terminal includes one or more processors, and a storage medium storing a computer-readable instruction, wherein, when the computer-readable instruction is executed by the one or more processors, the one or more processors are configured to measure an inter-terminal voltage due to contact resistance between rapid charging terminals provided in an inlet and an outlet, while rapid charging is performed, and determine whether the rapid charging terminal is deteriorated based on the measured inter-terminal voltage, and wherein the voltage is measured using a terminal not used for rapid charging among the terminals provided in the inlet and the outlet.

The terminal not used for the rapid charging may be a slow charging terminal.

The one or more processors may be configured to measure the voltage through a closed circuit including the rapid charging terminal and the slow charging terminal.

The closed circuit may include a first closed circuit including a first slow charging terminal among the slow charging terminals and a first rapid charging terminal among the rapid charging terminals, and a second closed circuit including a second slow charging terminal among the slow charging terminals and a second rapid charging terminal among the rapid charging terminals.

The one or more processors may be configured to measure a first inter-terminal voltage due to a first contact resistance between the first rapid charging terminals among the rapid charging terminals through the first closed circuit and to measure a second inter-terminal voltage due to a second contact resistance between the second rapid charging terminals among the rapid charging terminals through the second closed circuit.

The one or more processors may be configured to determine that the rapid charging terminal is deteriorated when at least one of the first inter-terminal voltage and the second inter-terminal voltage is greater than or equal to a predetermined first reference value.

The one or more processors may be configured to determine that the rapid charging terminal is deteriorated when either a slope of the first inter-terminal voltage or a slope of the second inter-terminal voltage is greater than or equal to a predetermined second reference value.

When the inlet and outlet comply with a combined charging system 1 (CCS1) charging connector standard, the slow charging terminals may be AC1 terminal and AC2 terminal.

When the inlet and outlet comply with a CCS2 charging connector standard, the slow charging terminals may be any two of the AC1 terminal, AC2 terminal, and AC3 terminal.

A relay may be provided in a slow charging line connected to the slow charging terminal of the inlet, and the relay is in an OFF state, while the rapid charging is performed.

According to another aspect of the present disclosure, a method of detecting a deterioration of a rapid charging terminal includes a first operation of measuring an inter-terminal voltage due to contact resistance between rapid charging terminals provided in an inlet and an outlet, while rapid charging is performed, and a second operation of determining whether the rapid charging terminal is deteriorated based on the measured inter-terminal voltage, wherein, in the first operation, the voltage is measured using a terminal not used for rapid charging among terminals provided in the inlet and the outlet.

The terminal not used for the rapid charging may be a slow charging terminal.

In the first operation, the voltage may be measured through a closed circuit including the rapid charging terminal and the slow charging terminal.

The closed circuit may include a first closed circuit including a first slow charging terminal among the slow charging terminals and a first rapid charging terminal among the rapid charging terminals, and a second closed circuit including a second slow charging terminal among the slow charging terminals and a second rapid charging terminal among the rapid charging terminals.

The first operation may include an operation of measuring a first inter-terminal voltage due to a first contact resistance between first rapid charging terminals among the rapid charging terminals through the first closed circuit, and an operation of measuring a second inter-terminal voltage due to a second contact resistance between second rapid charging terminals among the rapid charging terminals through the second closed circuit.

In the second operation, it may be determined that the rapid charging terminal is deteriorated when at least one of the first inter-terminal voltage and the second inter-terminal voltage is greater than or equal to a predetermined first reference value.

In the second operation, it may be determined that the rapid charging terminal is deteriorated when either a slope of the first inter-terminal voltage or a slope of the second inter-terminal voltage is greater than or equal to a predetermined second reference value.

When the inlet and outlet comply with a combined charging system 1 (CCS1) charging connector standard, the slow charging terminals may be AC1 terminal and AC2 terminal.

When the inlet and outlet comply with a CCS2 charging connector standard, the slow charging terminals may be any two of the AC1 terminal, AC2 terminal, and AC3 terminal.

A relay may be provided in a slow charging line connected to the slow charging terminal of the inlet, and the relay is in an OFF state, while the rapid charging is performed.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a drawing illustrating a charging system according to an embodiment of the present disclosure;

FIG. 2 is a drawing illustrating a terminal configuration of combined charging system 1 (CCS1) and CCS2 among charging connector standards;

FIG. 3 is a drawing illustrating a block diagram of an apparatus of detecting a deterioration of a rapid charging terminal according to an embodiment of the present disclosure;

FIG. 4 is a flowchart illustrating a method of detecting a deterioration of a rapid charging terminal according to an embodiment of the present disclosure; and

FIG. 5 is a block diagram of a computing device that may fully or partially implement a control module of an apparatus of detecting a deterioration of a rapid charging terminal according to an embodiment of the present disclosure.

### DETAILED DESCRIPTION

Hereinafter, embodiments of the present disclosure are described with reference to the accompanying drawings. The following description is provided to aid in the comprehensive understanding of methods, devices, and/or systems disclosed in the particularities. However, the following description is merely exemplary and not provided to limit the present disclosure.

In the following description of the present disclosure, a detailed description of known functions and configurations incorporated herein will be omitted when it would render the subject matter of the present disclosure unclear. The terms used in the present specification are defined in consideration of functions used in the present disclosure, and may be changed according to the intent or conventionally used methods of clients, operators, and users. Accordingly, definitions of the terms should be understood on the basis of the entire description of the present specification. Terms used in the following description are merely provided to describe embodiments of the present disclosure and are not intended to be limiting of the inventive concept. As used herein, the singular forms “a,” “an” and “the” are intended to include the plural forms as well, unless the context clearly indicates otherwise. It will be further understood that the terms “comprises” or “has” when used in this specification, specify the presence of stated features, integers, steps, operations, elements, or a portion or combination thereof, but do not preclude the presence or addition of one or more other features, integers, steps, operations, elements, or a portion or combination thereof.

Hereinafter, specific embodiments of the present disclosure will be described with reference to the drawings.

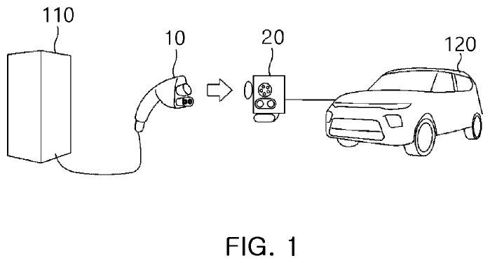

FIG. 1 is a drawing illustrating a charging system according to an embodiment of the present disclosure.

As illustrated in FIG. 1, a charging system may include a charging facility 110 and an electric vehicle 120. In the present disclosure, the electric vehicle 120 may include a high-voltage battery charged by the charging facility 110 and may include a plug-in hybrid electric vehicle (PHEV) in addition to a pure electric vehicle.

The charging facility 110 may be equipped with an outlet 10, and correspondingly, the electric vehicle 120 may also be equipped with an inlet 20, and after the outlet 10 is connected to the inlet 20, the electric vehicle 120 may be charged by the charging facility 110. This charging facility 110 may be a slow charging facility or a rapid charging facility.

The rapid charging facility supplies direct current (DC) power to the electric vehicle 120 to directly charge the high-voltage battery of the electric vehicle 120 and may perform rapid charging within approximately 30 minutes. Meanwhile, the slow charging facility may supply AC power to the electric vehicle 120 and may charge the high-voltage battery using an on-board charger (OBC) in the electric vehicle 120 and may perform slow charging for approximately 6 to 8 hours.

In the present disclosure, a deterioration of a rapid charging terminal is detected, while rapid charging is performed, and hereinafter, the charging facility 110 is limited to a rapid charging facility.

Meanwhile, the outlet 10 and the inlet 20 may include an inlet including a plurality of terminals for rapid charging and slow charging according to a charging connector standard.

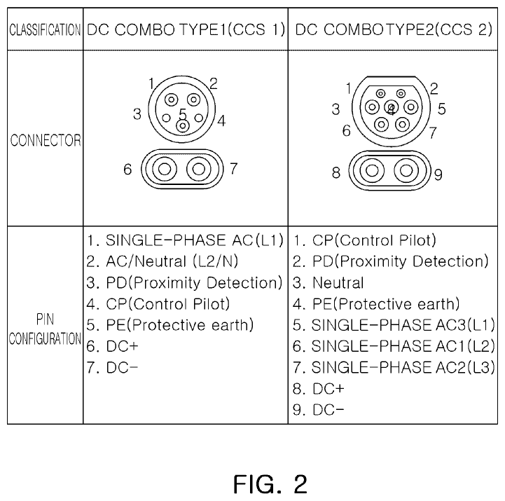

FIG. 2 is a drawing illustrating a configuration of terminals (pins) of combined charging system 1 (CCS1) and CCS2 in the charging connector standard. CCS1 may be referred to as DC combo type 1, and CCS2 may be referred to as DC combo type 2.

As illustrated in FIG. 2, according to CCS1, two AC terminals L1 and L2/N, a proximity detection (PD) terminal, a control pilot (CP) terminal, a protective earth (PE) terminal, and DC terminals DC+ and DC− may be provided in the inlet.

Hereinafter, the two AC terminals L1 and L2/N are slow charging terminals, which are referred to as AC1 terminal and AC2 terminal, respectively. In addition, the two DC terminals DC+ and DC− are rapid charging terminals, which are referred to as DC1 terminal and DC2 terminal, respectively.

In addition, according to CCS2, three AC terminals L1, L2, and L3, a neutral terminal, a PD terminal, a CP terminal, a PE terminal, and DC terminals DC+and DC-may be provided in the inlet. Similarly, the three AC terminals L1, L2, and L3 are slow charging terminals and are referred to as AC1 terminal, AC2 terminal, and AC3 terminal, respectively. In addition, the two DC terminals DC+ and DC− are rapid charging terminals and are referred to as DC1 terminal and DC2 terminal, respectively.

According to the charging connector standard, during rapid charging, the rapid charging terminal is used and the slow charging terminal is not used. Meanwhile, during slow charging, the slow charging terminal is used and the rapid charging terminal is not used.

According to an embodiment of the present disclosure, it is possible to determine whether the rapid charging terminal is deteriorated by using the slow charging terminal which is not used during rapid charging.

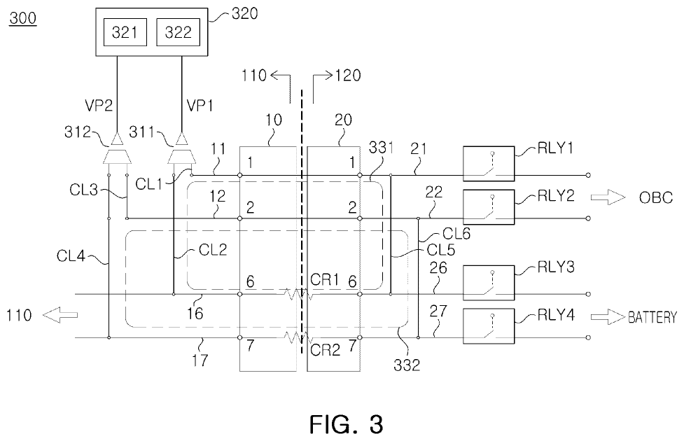

Hereinafter, an apparatus of detecting a deterioration of a rapid charging terminal according to an embodiment of the present disclosure is described in detail with reference to FIG. 3.

FIG. 3 is a block diagram illustrating an apparatus 300 of detecting a deterioration of a rapid charging terminal according to an embodiment of the present disclosure.

As illustrated in FIGS. 1 to 3, the outlet 10 on the side of the rapid charging facility 110 includes two slow charging terminals 1 and 2 and two rapid charging terminals 6 and 7, and the inlet 20 on the side of the electric vehicle 120 coupled to the outlet 10 on the side of the rapid charging facility 110 may also include two slow charging terminals 1 and 2 and two rapid charging terminals 6 and 7.

Each of the two rapid charging terminals 6 and 7 provided on the outlet 10 may be connected to the rapid charging facility 110 through rapid charging lines 16 and 17 and may transfer the direct current (DC) power provided from the rapid charging facility 110 to the battery of the electric vehicle 120 through the inlet 20 while rapid charging is performed.

Meanwhile, each of the two slow charging terminals 1 and 2 provided in the outlet 10 may be connected to a slow charging facility through slow charging lines 11 and 12. Since the slow charging terminals 1 and 2 are not connected to the slow charging facility during rapid charging, the slow charging lines 11 and 12 connected to the slow charging terminals 1 and 2 may be in an open state.

In addition, each of the two slow charging terminals 1 and 2 provided in the inlet 20 is connected to the OBC via the slow charging lines 21 and 22, and the slow charging lines 21 and 22 may include two relays RL1 and RLY2. The two relays RL1 and RLY2 described above may be turned on during slow charging and turned off during rapid charging.

Similarly, each of the two rapid charging terminals 6 and 7 provided in the outlet 10 may be connected to the rapid charging facility 110 via the rapid charging lines 16 and 17.

In addition, each of the two rapid charging terminals 6 and 7 provided in the inlet 20 may be connected to the battery via the rapid charging lines 26 and 27, and the rapid charging lines 26 and 27 may include two relays RL3 and RLY4. The two relays RL1 and RLY2 may be turned on during rapid charging and turned off during slow charging.

Meanwhile, contact resistances CR1 and CR2 may be contact resistances between the rapid charging terminals 6 and 7 provided in the outlet 10 and the rapid charging terminals 6 and 7 provided in the inlet 20 when the outlet 10 and the inlet 20 are connected. That is, the contact resistances CR1 and CR2 may include a first contact resistance CR1 between the first rapid charging terminal 6 provided in the outlet 10 and the first rapid charging terminal 6 provided in the inlet 20 and a second contact resistance CR2 between the second rapid charging terminal 7 provided in the outlet 10 and the first rapid charging terminal 7 provided in the inlet 20.

Two voltage sensors 311 and 312 may be sensors for measuring a voltage between the terminals due to the contact resistances CR1 and CR2 while rapid charging is performed.

Here, among the two voltage sensors 311 and 312, a first inter-terminal voltage sensor 311 may be a sensor for measuring a first inter-terminal voltage VP1 by the first contact resistance CR1, and among the two voltage sensors 311 and 312, a second inter-terminal voltage sensor 312 may be a sensor for measuring a second inter-terminal voltage VP2 by the second contact resistance CR2.

A closed circuit including rapid charging terminals 6 and 7 and slow charging terminals 1 and 2 may be configured to measure the inter-terminal voltage by each of the contact resistances CR1 and CR2.

The closed circuits 331 and 332 may include a first closed circuit 331 including a first slow charging terminal 1 among the slow charging terminals 1 and 2 and a first rapid charging terminal 6 among the rapid charging terminals 6 and 7 and a second closed circuit 332 including a second slow charging terminal 2 among the slow charging terminals 1 and 2 and a second rapid charging terminal 7 among the rapid charging terminals 6 and 7.

To configure the closed circuit, as illustrated in FIG. 3, on the side of the rapid charging facility 110, a first input of the first inter-terminal voltage sensor 311 may be connected to the first slow charging line 11 opened through the first connection line CL1, and a second input of the first inter-terminal voltage sensor 311 may be connected to the first rapid charging line 16 through the second connection line CL2.

In addition, in the case of the rapid charging facility 110 side, the first input of the second inter-terminal voltage sensor 312 may be connected to the second slow charging line 12 opened through the third connection line CL3, and the second input of the second inter-terminal voltage sensor 312 may be connected to the second rapid charging line 17 through the fourth connection line CL4.

Meanwhile, in the case of the electric vehicle 120 side, the first slow charging line 21 may be connected to the first rapid charging line 26 through the fifth connection line CL5. In addition, the second slow charging line 22 may be connected to the second rapid charging line 27 through the sixth connection line C6.

The control module 320 may detect whether the rapid charging terminals 6 and 7 are deteriorated based on the inter-terminal voltages VP1 and VP2 due to the contact resistances CR1 and CR2 between the rapid charging terminals 6 and 7 measured by the voltage sensors 311 and 312. To this end, the control module 320 may include a controller 321 and a storage unit 322.

The aforementioned control module 320 may include a processor (e.g., a computer, a microprocessor, a CPU, an ASIC, a logic circuit, etc.) and a memory storing software instructions providing various functions when executed by the processor. Here, the processor and the memory may be implemented as separate semiconductor circuits. Alternatively, the processor and the memory may be implemented as a single integrated semiconductor circuit. There may be one or more processors.

Specifically, the controller 321 may measure the inter- terminal voltages VP1 and VP2 due to the contact resistances CR1 and CR2 between the rapid charging terminals 6 and 7 provided in the outlet 10 and the inlet 20 respectively using two voltage sensors 311 and 312 while rapid charging is performed, and determine whether the rapid charging terminals 6 and 7 are deteriorated based on the measured inter-terminal voltages VP1 and VP2.

At this time, the controller 312 may measure the voltage using a terminal not used for rapid charging among the terminals provided in the outlet 10 and the inlet 20. Here, the terminal not used for rapid charging may be the slow charging terminals 6 and 7.

According to an embodiment of the present disclosure, when the outlet 10 and the inlet 20 comply with the CCS1 charging connector standard, the slow charging terminals may be AC1 terminals and AC2 terminals.

According to another embodiment of the present disclosure, when the outlet 10 and the inlet 20 comply with the CCS2 charging connector standard, the slow charging terminals may be any two of the AC1 terminal, the AC2 terminal, and the AC3 terminal.

Specifically, the controller 321 may measure the voltage through the closed circuits 331 and 332 including the rapid charging terminals 1 and 2 and the slow charging terminals 6 and 7 while rapid charging is performed. While rapid charging is performed, relays RLY1 and RLY2 provided in the slow charging lines 21 and 22 may be in an OFF state, and relays RLY3 and RLY4 provided in the rapid charging lines 26 and 27 may be in an ON state.

The closed circuits 331 and 332 may include a first closed circuit 331 including the first slow charging terminal 1 among the slow charging terminals 1 and 2 and a first rapid charging terminal 6 among the rapid charging terminals 6 and 7 and a second closed circuit 332 including a second slow charging terminal 2 among the slow charging terminals 1 and 2 and a second rapid charging terminal 7 among the rapid charging terminals 6 and 7.

Specifically, the controller 321 may measure the first inter-terminal voltage VP1 by the first contact resistance CR1 between the first rapid charging terminals 6 among the rapid charging terminals 6 and 7 through the first closed circuit 331 and may measure the second inter-terminal voltage VP2 by the second contact resistance CR2 between the second rapid charging terminals 7 among the rapid charging terminals 6 and 7 through the second closed circuit 332.

Thereafter, the controller 321 may determine whether the rapid charging terminals 6 and 7 are deteriorated based on the measured inter-terminal voltages VP1 and VP2.

According to an embodiment of the present disclosure, the controller 321 may determine that the rapid charging terminals 6 and 7 are deteriorated if at least one of the first inter-terminal voltage VP1 and the second inter-terminal voltage VP2 is equal to or greater than a predetermined first reference value.

Here, the first reference value may be, for example, a value between two to ten times the voltage applied between the rapid charging terminals 6 and 7 in a non-deteriorated state. The specific numerical value of the first reference value is merely intended to help understanding of the present disclosure and may be set to be different depending on a material of the rapid charging terminals 6 and 7 or a magnitude of the direct current (DC) power supply, and thus, it should be noted that it is not limited to the specific numerical value.

According to another embodiment of the present disclosure, the controller 321 may determine that the rapid charging terminals 6 and 7 are deteriorated if either a slope of the first inter-terminal voltage VP1 or a slope of the second inter-terminal voltage VP2 is greater than a predetermined second reference value.

Here, the second reference value may be a value between 50 V/sec and 100 V/sec. The specific numerical value of the second reference value is merely intended to help understanding of the present disclosure and may be set to be different depending on the material of the rapid charging terminals 6 and 7 or the magnitude of the direct current (DC) power supply, and thus, it should be noted that it is not limited to the specific numerical value.

Meanwhile, when it is determined that the rapid charging terminals 6 and 7 are deteriorated, the controller 321 may reduce a charging current or stop charging.

Meanwhile, the storage unit 322 may store a program for implementing the aforementioned function of the controller 321.

As described above, according to an embodiment of the present disclosure, while rapid charging is performed, the inter-terminal voltage due to the contact resistance between the rapid charging terminals provided in the inlet and the outlet may be measured, and whether the rapid charging terminal is deteriorated may be determined using the measured inter-terminal voltage, and the voltage may be measured using a terminal not used in rapid charging, thereby detecting whether the rapid charging terminal is deteriorated during rapid charging.

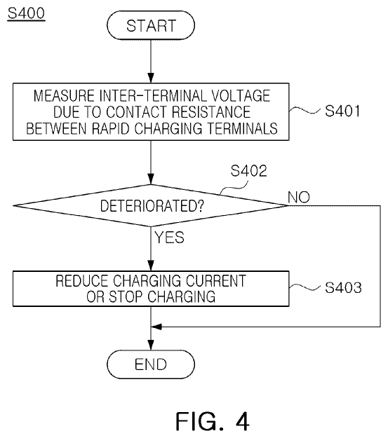

Meanwhile, FIG. 4 is a flowchart illustrating a method of detecting a deterioration of a rapid charging terminal according to an embodiment of the present disclosure.

Hereinafter, a method of detecting a deterioration of a rapid charging terminal according to an embodiment of the present disclosure is described with reference to FIGS. 1 to 4. However, for the sake of brevity, the same descriptions as those given above with reference to FIGS. 1 to 3 will be omitted.

Referring to FIGS. 1 to 4, a method (S400) of detecting a deterioration of a rapid charging terminal according to an embodiment of the present disclosure may start by an operation of measuring inter-terminal voltages VP1 and VP2 due to contact resistances CR1 and CR2 between the rapid charging terminals 6 and 7 while rapid charging is performed (S401).

Specifically, while rapid charging is performed, inter- terminal voltages VP1 and VP2 due to the contact resistances CR1 and CR2 between rapid charging terminals 6 and 7 provided in the outlet 10 and the inlet 20 may be measured using the two voltage sensors 311 and 312.

At this time, the apparatus 300 of detecting a deterioration of a rapid charging terminal may measure the voltage using a terminal not used for rapid charging among the terminals provided in the outlet 10 and the inlet 20. Here, the terminal not used for rapid charging may be the slow charging terminals 6 and 7.

According to an embodiment of the present disclosure, when the outlet 10 and the inlet 20 comply with the CCS1 charging connector standard, the slow charging terminals may be the AC1 terminal and the AC2 terminal.

According to another embodiment of the present disclosure, when the outlet 10 and the inlet 20 comply with the CCS2 charging connector standard, the slow charging terminals may be any two of the AC1 terminal, the AC2 terminal, and the AC3 terminal.

Meanwhile, the apparatus 300 of detecting a deterioration of a rapid charging terminal may measure the voltage through the closed circuits 331 and 332 including the rapid charging terminal 1 and 2 and the slow charging terminals 6 and 7 while rapid charging is performed.

The closed circuits 331 and 332 may include the first closed circuit 331 including the first slow charging terminal 1 among the slow charging terminals 1 and 2 and the first rapid charging terminal 6 among the rapid charging terminals 6 and 7 and the second closed circuit 332 including the second slow charging terminal 2 among the slow charging terminals 1 and 2 and the second rapid charging terminal 7 among the rapid charging terminals 6 and 7.

Specifically, the apparatus 300 of detecting a deterioration of a rapid charging terminal may measure the first inter-terminal voltage VP1 due to the first contact resistance CR1 between the first rapid charging terminals 6 among the rapid charging terminals 6 and 7 through the first closed circuit 331 and may measure the second inter-terminal voltage VP2 due to the second contact resistance CR2 between the second rapid charging terminals 7 among the rapid charging terminals 6 and 7 through the second closed circuit 332.

Thereafter, the apparatus 300 of detecting a deterioration of a rapid charging terminal may determine whether the rapid charging terminals 6 and 7 are deteriorated based on the measured inter-terminal voltages VP1 and VP2 (S402).

According to an embodiment of the present disclosure, the apparatus 300 of detecting a deterioration of a rapid charging terminal may determine that the rapid charging terminals 6 and 7 are deteriorated if at least one of the first inter-terminal voltage VP1 and the second inter-terminal voltage VP2 is greater than or equal to a predetermined first reference value.

Alternatively, according to another embodiment of the present disclosure, detecting the apparatus 300 of a deterioration of a rapid charging terminal may determine that the rapid charging terminals 6 and 7 are deteriorated if either the slope of the first inter-terminal voltage VP1 or the slope of the second inter-terminal voltage VP2 is greater than or equal to a predetermined second reference value.

If it is determined in step S402 that the rapid charging terminals 6 and 7 are deteriorated, the apparatus 300 of detecting a deterioration of a rapid charging terminal may reduce a charging current or stop charging (S403).

As described above, according to an embodiment of the present disclosure, while rapid charging is performed, the inter-terminal voltage due to the contact resistance between the rapid charging terminals provided in the inlet and the outlet may be measured and whether the rapid charging terminal is deteriorated may be determined using the measured inter-terminal voltage, and here, the voltage is determined using the terminal not used for rapid charging, thereby detecting whether the rapid charging terminal is deteriorated during rapid charging.

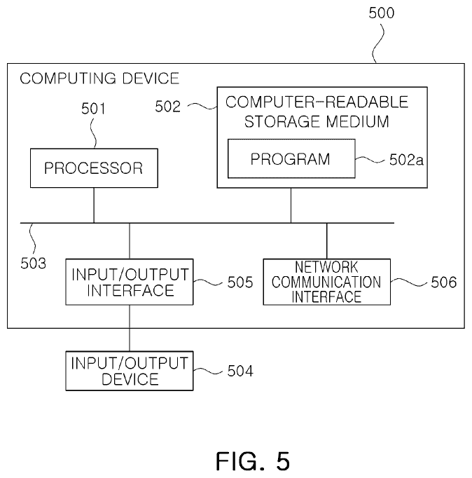

Finally, FIG. 5 is a block diagram of a computing device 500 that may fully or partially implement the control module 320 of the apparatus 300 of detecting a deterioration of a rapid charging terminal according to an embodiment of the present disclosure.

As illustrated in FIG. 5, the computing device 500 includes at least one processor 501, a computer-readable storage medium 502, and a communication bus 503.

The processor 501 may cause the computing device 500 to operate according to the embodiment mentioned above. For example, the processor 501 may execute one or more programs stored on the computer-readable storage medium 502. The one or more programs may include one or more computer-executable instructions, which, when executed by the processor 501, may be configured to cause the computing device 500 to perform the operations according to the embodiments described herein.

The computer-readable storage medium 502 is configured to store computer-executable instructions or program code, program data, and/or other suitable forms of information. A program 502a stored in the computer-readable storage medium 502 includes a set of instructions executable by the processor 501. In an embodiment, the computer-readable storage medium 502 may be memory (a volatile memory, such as random access memory, a nonvolatile memory, or appropriate combinations thereof), one or more magnetic disk storage devices, optical disk storage devices, flash memory devices, or any other form of storage medium which is accessible by the computing device 500 and capable of storing desired information, or appropriate combinations thereof.

The communication bus 503 interconnects various other components of the computing device 500, including the processor 501, the computer-readable storage medium 502.

The computing device 500 may also include one or more input/output interfaces 505 providing interfaces for one or more input/output devices 504 and one or more network communication interfaces 506. The input/output interfaces 505 and the network communication interfaces 506 are connected to the communication bus 503. The network may be any one of cellular networks, such as global system for mobile communications (GSM), enhanced data rates for GSM Evolution (EDGE), general packet radio service (GPRS), code division multiple access (CDMA), time division-CDMA (TD-CDMA), universal mobile telecommunications system (UMTS), long term evolution (LTE), or other cellular networks.

The input/output device 504 may be connected to other components of the computing device 500 via the input/output interface 505. For example, the input/output devices 504 may include input devices, such as a pointing device (such as a mouse or a trackpad), a keyboard, a touch input device (such as a touchpad or a touchscreen), a voice or sound input device, various types of sensor devices and/or imaging devices, and/or output devices, such as a display device, a printer, a speaker, and/or a network card. For example, the input/output device 504 may be a component constituting the computing device 500 and included within the computing device 500 or may be a separate device distinct from the computing device 500 and connected to the computing device 500.

According to an embodiment of the present disclosure, while rapid charging is performed, the inter-terminal voltage due to the contact resistance between rapid charging terminals provided in the inlet and outlet may be measured and whether the rapid charging terminal is deteriorated may be determined using the measured inter-terminal voltage, and here, the voltage may be measured using a terminal not used for rapid charging, thereby detecting whether the rapid charging terminal is deteriorated during rapid charging.

Meanwhile, the embodiments of the present disclosure may include a program for performing the methods described in this specification on a computer and a computer-readable recording medium including the program. The computer-readable recording medium may include program instructions, local data files, local data structures, etc., alone or in combination. The medium may be those specifically designed and configured for the present disclosure or may be those commonly available in the computer software field. Examples of computer-readable recording medium include magnetic medium, such as hard disks, floppy disks, and magnetic tapes, optical recording medium, such as CD-ROMs, DVDS, and hardware devices specifically configured to store and perform program instructions, such as ROM, RAM, flash memory, etc. Examples of the program may include not only machine language code, such as that generated by a compiler, but also high-level language code that may be executed by a computer using an interpreter or the like.

While the present disclosure has been particularly illustrated and described with reference to embodiments thereof, a person skilled in the art will understand that the invention is not limited to the disclosed embodiments but may be variously modified within the scope of the present disclosure. Therefore, the scope of the present disclosure should not be limited to the aforementioned embodiments but should be determined by all changes or modifications derived from the scope of the appended claims and equivalents of the following claims.

What is claimed is:

1. An apparatus of detecting a deterioration of a rapid charging terminal, the apparatus comprising:
one or more processors; and
a storage medium storing a computer-readable instruction,
wherein, when the computer-readable instruction is executed by the one or more processors, the one or more processors are configured to:
measure an inter-terminal voltage due to a contact resistance between rapid charging terminals provided in an inlet and an outlet, while rapid charging is performed, and
determine whether rapid charging terminal is deteriorated based on the measured inter-terminal voltage,
wherein the voltage is measured using a terminal not used for rapid charging among the terminals provided in the inlet and the outlet.

2. The apparatus of claim 1, wherein the terminal not used for the rapid charging is a slow charging terminal.

3. The apparatus of claim 2, wherein the one or more processors are configured to measure the voltage through a closed circuit including the rapid charging terminal and the slow charging terminal.

4. The apparatus of claim 3, wherein
the closed circuit includes:
a first closed circuit including a first slow charging terminal among the slow charging terminals and a first rapid charging terminal among the rapid charging terminals; and
a second closed circuit including a second slow charging terminal among the slow charging terminals and a second rapid charging terminal among the rapid charging terminals.

5. The apparatus of claim 4, wherein the one or more processors are configured to measure a first inter-terminal voltage due to a first contact resistance between the first rapid charging terminals among the rapid charging terminals through the first closed circuit and to measure a second inter-terminal voltage due to a second contact resistance between the second rapid charging terminals among the rapid charging terminals through the second closed circuit.

6. The apparatus of claim 5, wherein the one or more processors are configured to determine that the rapid charging terminal is deteriorated when at least one of the first inter-terminal voltage and the second inter-terminal voltage is greater than or equal to a predetermined first reference value.

7. The apparatus of claim 5, wherein the one or more processors are configured to determine that the rapid charging terminal is deteriorated when either a slope of the first inter-terminal voltage or a slope of the second inter-terminal voltage is greater than or equal to a predetermined second reference value.

8. The apparatus of claim 2, wherein, when the inlet and outlet comply with a combined charging system 1 (CCS1) charging connector standard, the slow charging terminals are AC1 terminal and AC2 terminal.

9. The apparatus of claim 2, wherein, when the inlet and outlet comply with a CCS2 charging connector standard, the slow charging terminals are any two of the AC1 terminal, AC2 terminal, and AC3 terminal.

10. The apparatus of claim 2, wherein a relay is provided in a slow charging line connected to the slow charging terminal of the inlet, and the relay is in an OFF state, while the rapid charging is performed.

11. A method of detecting a deterioration of a rapid charging terminal, the method comprising:
a first operation of measuring an inter-terminal voltage due to contact resistance between rapid charging terminals respectively provided in an inlet and an outlet, while rapid charging is performed; and
a second operation of determining whether the rapid charging terminal is deteriorated based on the measured inter- terminal voltage,
wherein, in the first operation, the voltage is measured using a terminal not used for rapid charging among terminals provided in the inlet and the outlet.

12. The method of claim 11, wherein the terminal not used for the rapid charging is a slow charging terminal.

13. The method of claim 12, wherein, In the first operation, the voltage is measured through a closed circuit including the rapid charging terminal and the slow charging terminal.

14. The method of claim 13, wherein
the closed circuit includes:
a first closed circuit including a first slow charging terminal among the slow charging terminals and a first rapid charging terminal among the rapid charging terminals; and
a second closed circuit including a second slow charging terminal among the slow charging terminals and a second rapid charging terminal among the rapid charging terminals.

15. The method of claim 14, wherein
the first operation includes:
an operation of measuring a first inter-terminal voltage due to a first contact resistance between first rapid charging terminals among the rapid charging terminals through the first closed circuit; and
an operation of measuring a second inter-terminal voltage due to a second contact resistance between second rapid charging terminals among the rapid charging terminals through the second closed circuit.

16. The method of claim 15, wherein, in the second operation, it is determined that the rapid charging terminal is deteriorated when at least one of the first inter-terminal voltage and the second inter-terminal voltage is greater than or equal to a predetermined first reference value.

17. The method of claim 15, wherein, in the second operation, it is determined that the rapid charging terminal is deteriorated when either a slope of the first inter-terminal voltage or a slope of the second inter-terminal voltage is greater than or equal to a predetermined second reference value.

18. The method of claim 12, wherein, when the inlet and outlet comply with a combined charging system 1 (CCS1) charging connector standard, the slow charging terminals are AC1 terminal and AC2 terminal.

19. The method of claim 12, wherein, when the inlet and outlet comply with a CCS2 charging connector standard, the slow charging terminals are any two of the AC1 terminal, AC2 terminal, and AC3 terminal.

20. The method of claim 12, wherein a relay is provided in a slow charging line connected to the slow charging terminal of the inlet, and the relay is in an OFF state, while the rapid charging is performed.
